(19) United States
(12) Patent Application Publication
(10) Pub. No.: US 2011/0037981 A1
(43) Pub. Date: Feb. 17, 2011

(54) WAVE-GUIDE COUPLING SPR SENSOR CHIP AND SENSOR CHIP ARRAY THEREOF

(75) Inventors: Jinsong Zhu, Beijing (CN); Xinlong Xu, Beijing (CN); Jiangfeng Fan, Beijing (CN); Kun Wang, Beijing (CN); Chen Wang, Beijing (CN); Anthony D. Piscopio, Longmont, CO (US)

Correspondence Address: CONNOLLY BOVE LODGE & HUTZ, LLP, P O BOX 2207, WILMINGTON, DE, 19899, US

(73) Assignee: National Center for Nanoscience and Technology, China, Haidian District, Beijing (CN)

(21) Appl. No.: 12/676,672

(22) PCT Filed: Sep. 6, 2007
(86) PCT No.: PCT/CN2007/002664

§ 371 Date: Oct. 25, 2010

(51) Int. Cl. G01J 4/04; H01L 27/144; H01L 31/0232

(52) U.S. Cl. 356/369; 257/432; 438/69; 257/E27.127; 257/E31.127

(57) ABSTRACT

A sensor chip based on the WCSPR effect and an array thereof are disclosed. The sensor chip is a multilayer structure comprising a substrate, a dielectric waveguide layer (26) disposed on the substrate and a first metal layer (27) disposed on the dielectric waveguide layer (26), wherein parameters of physical properties of the dielectric waveguide layer (26) are tunable.

### FIELD OF THE INVENTION

The present invention relates to the field of sensor and sensing technology, and more specifically to a Surface Plasmon Resonance (SPR) detection method with high resolution and fast response, a detection device and a detection array for implementing the method and the use thereof.

### BACKGROUND ART OF THE INVENTION

Surface Plasmon (SP) is an oscillation mode resulted from the collective oscillation of charges on a metal surface propagating along a metal-dielectric interface. SP waves are found at the interface between two materials (generally metal and dielectric) with opposite-signed dielectric constants. The field intensity of this mode reaches the maximum at the interface, and decays exponentially in a direction normal to the interface on both sides of the surface. As a result, the modal field is restricted to the vicinity of the interface. The dispersion relation of the SP waves is expressed as:

$${k}_{sp} = \frac{2 π}{λ} {( \frac{{ɛ}_{1} {ɛ}_{2}}{{ɛ}_{1} + {ɛ}_{2}} )}^{1 / 2} = \frac{ω}{c} {( \frac{{ɛ}_{1} {ɛ}_{2}}{{ɛ}_{1} + {ɛ}_{2}} )}^{1 / 2} \qquad ( 1 )$$

where kₛₚ is the propagation coefficient of the SP waves on the metal surface, λ, ω, c are the wavelength, angular frequency of the SP waves and the velocity of the light, respectively, and ∈₁ and ∈₂ are the dielectric coefficients of the metal layer and the dielectric layer, respectively.

Surface Plasmon Resonance (SPR) is the excitation of SP waves by light waves, which is a phenomenon in physical optics. Energy may be coupled from the light waves to the plasmon waves by means of the Attenuated Total Reflection (ATR) method, which utilizes the coupling between the evanescent waves and the plasmon resonance mode on the metal surface when total internal reflection occurs at the prism interface; the free electrons on the metal surface are thereby excited to generate surface plasma oscillation. When a linear-polarized light wave having an electric field component parallel to the incident plane is incident on the interface at a specific angle, the energy of the reflected light is smaller than that of the total reflection. In this case, the wave vector of the surface plasmon is matched with that of the evanescent waves, and the energy of the incident light is coupled to the surface plasmon, which significantly reduces the energy of the reflection light. This specific angle is referred to as a SPR angle. A resonance peak (i.e., with minimum reflection strength) may be determined on the reflection spectrum through angular interrogation. A phase matching relation may be expressed as:

kₓ=k sin θ=kₛₚ (2)

where k is the wave vector of the evanescent waves, kₓ is a horizontal component of the wave vector of the evanescent waves that is parallel to the total reflection plane, and θ is the angle between the wave vector of the light waves and the normal line (a direction normal to the total reflection plane). It can be seen from Equations (1) and (2) that the resonance peak of the reflection will occur at a different location when the refractive index of the dielectric in contact with the thin metal film surface is different. The SPR is so sensitive to the refractive index of the dielectric on the metal surface that the SPR angles for different dielectrics are different. Even for the same kind of dielectric, a very thin layer of the dielectric may give a different SPR angle due to the difference in its thickness. It is seen from both cases that the resonance peak, i.e., the location and intensity of the resonance peak, is influenced by the equivalent index of refraction of the dielectric, which is the mechanism on which various sensors are based. The parameters of physical properties of the dielectric on the metal surface and their amount of variation may be obtained by measuring the location and variation of the SPR angle. Considering the sensitivity of the SPR to the change of the surface, the SPR technology is especially suitable for such applications as sensing detection having fine and high-precision requirement.

Based on the above SPR technology, various researches have been done with respect to various dielectric-metal structures and their sensitivities, with an aim of improving the sensitivity, signal to noise ratio (SNR) and resolution of the plasmon resonance sensors. Most of the researches focus on the improvements in the SPR detection structure and the SPR signal interrogation method.

Long-Range Surface Plasmon Resonance (LRSPR, Applied Optics, 1983□ vol 27, p 4587-4590) is a mode resulted from the coupling of the SP waves generated simultaneously on both the upper and lower surfaces of a thin metal film. A device having the LRSPR effect comprises a dielectric layer, a metal layer and a detected dielectric layer. The resonance peak of the LRSP is sharper than a normal resonance peak, thereby improving the detection to sensitivity, resolution and SNR. Unfortunately, the LPSRP can only be excited when the refractive indices of the dielectrics on both sides of the metal are similar. As a result, it is not easy to actually apply the LRSPR to complicated detection environments.

Coupled Plasmon Waveguide Resonance (CPWR, Biophysical Journal, 1997, vol 73, p 2791-2797) mostly occurs in a structure comprising a metal layer, a waveguide layer and a detected dielectric layer. The CPWR can obtain the parameters of the analyte by monitoring the change of the environment using waveguide modes. Such a method has the advantages of providing a very high SNR and more operational modes, comparing with the conventional SPR. However, this method suffers for low sensitivity.

The fundamental structure of the Waveguide Coupled Surface Plasmon Resonance (WCSPR, Biosensors and Bioelectronics, 2004, vol 20, p 633-642) generally comprises a metal layer 1, a dielectric waveguide layer 2, a metal layer 3 and a detected layer 4 (see FIG. 1). The WCSPR is a mode having stronger resonance which combines the advantages of both the conventional SPR and the CPWR and has high sensitivity, high SNR and high dynamic measurement range.

It can be seen from Equations (1) and (2) that the condition for the SPR to occur is a function of both the wavelength and the incident angle of the incident wave. Thus, the currently-applied SPR signals are mainly obtained based on the following three kinds of interrogation methods of changing the incident light conditions.

1. Angular Interrogation: this is an interrogation method most commonly used in the conventional SPR sensor which makes use of a fixed-wavelength light source. The SPR angle is determined by changing the incident angle (i.e., kₓ) of the incident light at the interface of the SPR detection mechanism through rotating the SPR detection mechanism or the incident light source using a mechanical device. Though the Angular Interrogation is straightforward and simple, it has various drawbacks and disadvantages. The precision and sensitivity of the interrogation method depend on the precision of the mechanical rotating table (component), e.g., the resolution of the to rotating angle. Under the restriction of the angular position deviation and the noise in the intensity of the reflected light, the angular resolution achievable by rotating the prism is generally in the range of 10^{-2□}10⁻³ degree. The angular resolution may be improved to a certain extent by increasing the distance between the prism and the photoelectrical detector. However, the resulting apparatus will be too bulky and more vulnerable to the mechanical noise and thermal drift. Moreover, the scanning speed of the system is very low due to the fact that the operational speed of the precise mechanical rotating table is limited. Thus, it is difficult to realize fast real-time measurement with high time resolution. Neither is multi-channel parallel detection possible for this interrogation method. Besides, the precise mechanical control rotating table needed for angular interrogation is of high maintenance cost and bulky volume, and frequent calibration is required. Thereby, it is difficult for the angular interrogation to be used in compact and portable instruments.

2. Wavelength Interrogation: with this interrogation method, the incident angle is fixed, the responses to incident lights having different wavelengths are measured by changing the wavelengths of the incident lights or employing a wide-spectrum light source, and the wavelength of the light that may cause the SPR is thereby determined. The sensitivity of the method depends on the wavelength resolution of the wavelength-tunable laser or spectrometer and is thereby lower than that of the angular interrogation which utilizes a high-precision rotating table. Moreover, the cost for realizing high resolution with the method is very high; the volume of the involved device is hard to reduce and the scanning speed is limited.

3. Intensity Interrogation: here a focused beam is used as the incident light instead of the generally-used quasi-planar beam. The focused beam is composed of planar waves having different wave vectors k, therefore a certain range of incident angles may be covered without changing the central incident angle. When the direction of a certain wave vector k in the beam meets the SPR condition, its reflectivity will be lower than those in other directions. The spatial angle satisfying the SPR condition may be found by measuring the strength distribution of the reflected light at various spatial angles. The method to may be implemented with a spatial light detector array device (e.g., a CCD), thus, the detection is done relatively quickly. However, the achieved detection sensitivity of the Intensity Interrogation is the lowest among the three methods, due to the limitation of the number of detectors used in the array. Moreover, it is not suitable for high density multi-channel parallel detections.

In the above, several SPR detection structures and SPR signal interrogation methods are described in detail, from which it can be seen that the following problems have to be solved when the SPR is used as sensors, i.e., low precision and sensitivity, low system interrogation speed, bulky volume, and not being able to carry out high density multi-channel parallel detections.

### SUMMARY OF THE INVENTION

An objective of the invention is to provide a sensor chip based on the WCSPR effect that overcomes the drawbacks of the conventional surface plasmon sensing technology.

Another objective of the invention is to provide a manufacturing method for the above sensor chip.

Still another objective of the invention is to provide a measuring system that utilizes the above sensor chip.

Still another objective of the invention is to provide a measuring method using the above measuring system.

Still another objective of the invention is to provide a sensor chip array based on the WCSPR effect.

Still another objective of the invention is to provide a measuring system using the above sensor chip array.

In one aspect, a sensor chip based on the WCSPR effect is disclosed in the present invention. The sensor chip is in a multilayer structure, comprising: a substrate, a dielectric waveguide layer disposed on the substrate and a first metal layer disposed on the dielectric waveguide layer, wherein parameters of physical properties of the dielectric waveguide layer are tunable.

In the above sensor chip, the parameter of the physical properties of the dielectric waveguide layer is preferably its refractive index or thickness. The above sensor chip further comprises a detected layer, a material of which is a detected substance, a decorative substance, a label substance and combinations thereof.

In the above sensor chip, a material of the dielectric waveguide layer is a material having a tunable index of refraction, such as an electro-optical material, a magneto-optical material, a thermo-optical material or an acousto-optical material, or a material having a tunable thickness, such as a piezocrystal.

Furthermore, the electro-optical material is a material whose refractive index is responsive to the change of the electrical field, that is, it is a material having the Electro-Optical Effect, which includes an inorganic electro-optical material, such as LiNbO₃, KDP, ADP, KD*P or LiTaO₃ etc., and an organic electro-optical material and compound thereof, such as DAST(4-Methylamino-N-Methyl-stilbene Tosylate) etc.

The magneto-optical material is a material whose refractive index is responsive to the change of the magnetic field, that is, it is a material having the Magneto-Optical Effect, which includes a metal magneto-optical material such as Mn—Bi based alloy etc., a ferrite magneto-optical material such as garnet Bi—Gd—Fe—Ga-0 based ferrite etc., and an amorphous magneto-optical material such as Gd—Co based amorphous alloy etc.

The thermo-optical material is a material whose refractive index is responsive to the change of temperature, that is, it is a material having the thermo-optical effect, such as optical glass etc.

The acousto-optical material is a material whose refractive index is responsive to the change of the property of acoustic waves, that is, it is a material having the acousto-optical effect, such as PbMoO₄, TeO₂ and Tl₃AsS₄ and the like.

In the above sensor chip, the thickness of the dielectric waveguide layer has to be selected and controlled strictly, such that the waveguide mode needed for the measurement is obtained. The thickness of the dielectric waveguide layer is generally larger than the wavelength of the incident light and less than 100 μm, and preferably in the range of 1 μm-10 μm.

A material of the substrate is optical glass or polymer, and parameters, such as the thickness and optical loss of the substrate material should not harm the detection performance of the sensor.

A second metal layer may be further included when the dielectric waveguide layer is of the electro-optical material. The second metal layer is is disposed between the substrate and the dielectric waveguide layer.

A material of the first and second metal layers is one kind of metal, an alloy or a metallic compound. Such kind of metal is preferably Au, Ag, Cr, Cu or Al, the alloy is preferably Cr—Au, Ti—Au, Au—Ag, Cu—Ni or Al—Ni, and the metallic compound is preferably a transparent conductive material, such as ITO etc. Irregularities of the first and second metal layers and the dielectric waveguide layer should be limited in a range of not obviously harming the detection sensitivity and precision of the sensor.

In the above sensor chip, the first metal layer may be in a single layer or multilayer structure.

In the above sensor chip, the second metal layer may be in a single layer or multilayer structure.

A thickness of the first metal layer is preferably in the range of 10 nm to 200 nm, and most preferably 20 nm to 50 nm.

A thickness of the second metal layer is preferably in the range of 10 nm to 200 nm, and most preferably 20 nm to 50 nm.

In the above sensor chip, the dielectric waveguide layer is in a multilayer structure.

The above sensor chip further comprises a refractive index matching layer that is adapted to eliminate interference from air gap and to facilitate effective coupling of the light path. A material of the refractive index matching layer is refractive index matching liquid or refractive index matching film. The function of the refractive index matching layer is to effectively couple the incident light to the corresponding functional layers of the sensor and to eliminate the possible interference from the air gap present on the interface. The parameters, such as the material property and thickness of the refractive index matching layer, should not harm the WCSPR detection function of the sensor and the tuning function of the dielectric waveguide layer.

The above sensor chip further comprises an isolating layer for preventing substance leakage between the layers. A material of the isolating layer is Al₂O₃ or SiO₂. The parameters, such as the material property and thickness of the isolating layer, should not harm the WCSPR detection function of the sensor and the tuning function of the dielectric waveguide layer.

The above sensor chip further comprises an intermediate layer for increasing the adhesive forces between the layers. A material of the intermediate layer is Cr, Ti or Ni or an alloy containing the above metal. The parameters, such as the material property and thickness of the intermediate layer, should not harm the WCSPR detection function of the sensor and the tuning function of the dielectric waveguide layer.

In another aspect, the invention provides a manufacturing method of the sensor chip in the above sensor. The method comprises the steps of: preparing each layer structure sequentially in a bottom-up order on the substrate, including a dielectric waveguide layer, a first metal layer and/or detected layer, and a second metal layer, a refractive index matching layer, an isolating layer or an intermediate layer between each layer which are added as required by the design.

In the above manufacturing method, a method for preparing each layer may be a conventional film making method which does not harm the WCSPR detection function of the sensor.

Furthermore, a method for preparing the first and second metal layers can be, but not limited to, those methods for preparing a metal film, such as Vacuum Evaporation, Vacuum Sputtering, Chemical Vapor Deposition or Electrochemical Deposition.

Furthermore, a method for preparing the dielectric waveguide layer can be, but not limited to, those methods for preparing a film, such as Vacuum Evaporation, spin-coating, Chemical Vapor Deposition, etc.

Furthermore, a method for preparing the detected layer can be, but not limited to, those methods for preparing a film, such as molecule self-assembly, stamp print, etc.

In another aspect, the invention provides a measuring system based on the to above sensor chip structure, comprising a polarized light generator, a light coupler, a light detector, a conveying system, a control system and a field control device for applying electrical field, magnetic field, acoustic field or temperature control to the dielectric waveguide layer, wherein the polarized light emitted from the polarized light generator is incident onto the substrate of the sensor chip through the light coupler and then fed into the light detector after being reflected by the sensor chip.

In the above measuring system, the polarized light generator includes, but is not limited to, a light source, a polarizing plate and a half-wave plate sequentially arranged in a light path. The polarized light generator is adapted to provide single-mode (TM mode) incident polarized light for the sensor.

In the above measuring system, the light coupler is a device for coupling the incident polarized light emitted by the polarizing light generator to the sensor chip. The light coupler may be a prism, a grating or other optical devices for coupling polarized light to the sensor chip.

In the above measuring system, the light detector is a device for measuring properties of the emergent light from the sensor chip. The properties of the emergent light measured by the light detector may be parameters such as intensity and phase of the emergent light. The light detector may be a semiconductor light intensity detector, a CCD detector or other apparatus and devices that may record optical-related parameters.

In the above measuring system, the conveying system is a system device for performing operations such as feeding, preprocessing, transporting, pumping, storing, and exiting on the detected samples. The above conveying system may be a microflow channel, a sample pool and the like according to the actual need.

Furthermore, the conveying system also comprises auxiliary devices, which comprise but are not limited to, a feeder, a control pump, a preprocessor and the like.

In the above measuring system, the control system is a software and hardware system for performing system control, data acquisition, data analysis and data transportation on the sensor.

In another aspect, the invention provides a measuring method based on the above sensor measuring system. The method comprises the steps of:

(1) projecting the polarized light generated by the polarized light generator to the sensor chip and adjusting an incident angle of the incident polarized light to allow parameters of the emergent light on the detector to be at a characteristic position of the resonance peak;

(2) feeding a detected sample into the conveying system;

(3) adjusting the field control device to apply an external field on the sensor chip, making parameters of the emergent light on the detector return to the characteristic position of the resonance peak;

(4) obtaining a biochemical or physiochemical property of the detected sample by comparing the applied external field in the above step (3) to a correspondence relation between known external fields and biochemical or physiochemical properties of the detected sample.

In the above measuring method, the resonance peak is preferably a WCSPR peak, the parameters of the emergent light are preferably light intensity and phase, and the characteristic position is preferably where the intensity of the emergent light reaches a the minimum or has a point of inflection.

In another aspect, a sensor chip array may be made using the above sensor chip provided by the invention. The sensor chip array is an array structure having the sensor chips as the elements.

In the above sensor chip array, the sensor chips form the sensor chip array according to a certain topology structure. The topology structure meets the requirements of making the detection locations addressable and feeding and conveying samples at specified locations in the sensor chip array.

In another aspect, the invention discloses a sensor chip array made by the above sensor chip, comprising a second metal layer, a dielectric waveguide layer and a first metal layer sequentially disposed on the a substrate, wherein the first and second metal layers are each made up of a plurality of thin metal film strips parallel to and electrically insulated from each other; the width of the thin metal film strips is larger than a propagation length that may excite SP waves; the thin metal film strip of the first metal layer and that of the second metal layer overlap with each other, and a dielectric waveguide layer is arranged between the above and below thin metal film strips at the intersecting sections. In the sensor chip array, a specific thin metal film strip of the first metal layer and a specific think metal film strip of the second metal layer are connected to an external electrical field, thereby realizing electrical-field addressing and tuning for the dielectric waveguide layers between the intersecting sections of the two metal layers. The sensor chip array maybe single-point addressed or multi-point addressed.

In another aspect, the invention provides a method for manufacturing the above sensor chip array, wherein the structure of each layer is prepared sequentially in a bottom-up order on the substrate.

In the above manufacturing method, a method for preparing the first and second metal layers is Vacuum Evaporation, Vacuum Sputtering, Chemical Vapor Deposition, or Electrochemical Deposition.

In the above manufacturing method, a method for preparing the dielectric waveguide layer is Vacuum Evaporation, Chemical Vapor Deposition or spin-coating.

In another aspect, the invention discloses a measuring system based on the sensor chip array, comprising a polarized light generator, a light coupler, a light detector, a conveying system, a control system and a field control device for applying an electrical field, magnetic field, acoustic field or temperature control to the dielectric waveguide layer, wherein the polarized light emitted from the polarized light generator is incident onto the substrate of the sensor chip through the light coupler and then fed into the light detector after being reflected by the sensor chip.

In the above measuring system, an output of the polarized light generator is preferably a wide beam polarized light or an array of polarized light.

In the above measuring system, the optical coupler is preferably a grating, a prism or a prism array.

In the above measuring system, the light detector is preferably a semiconductor light intensity detector, a semiconductor light intensity detector array or a CCD.

The invention has the following advantages:

1. A material having tunable optical properties is used as the dielectric waveguide layer of the WCSPR-based sensor chip of the invention, and the properties of the WCSPR structure, such as the response of the WCSPR signal, may be effectively tuned by adjusting the refractive index of the dielectric waveguide layer via changing such conditions as the electrical field, the magnetic field or the temperature. By using a material having the Optical Effect as the optical dielectric layer of the WCSPR detection structure, the optical properties (such as the refractive index, etc.) of the dielectric layer may be tuned quickly and precisely;

2. When the electro-optical material is used for the dielectric waveguide layer, both inorganic material and organic polymer material may be used to precisely control the voltage and the resulted change of the index of refraction, the interrogation precision is thereby higher. Meanwhile, the response speed of the electronic-interrogation system is much higher than that of the mechanical-interrogation scheme, thus, such an interrogation method allows for a faster and simpler detection. At the same time, in the sensing system realized according to the method of the invention, the light source, detection structure and light detector may be fixed or even be smaller in size, which helps to make them compact and portable;

3. The system using the sensor chip array of the invention helps to carry out a biochemical dynamical procedure of simultaneously detecting numerous working points quickly and efficiently, thereby realizing multi-channel real-time biochemical detection, which is suited for the fields such as biological research, medical diagnosis, pharmaceutical selection, food detection and environment protection; and

4. The tunable optical dielectric layer in the WCSPR detection structure according to the invention may be realized using the materials having the electro-optical effect (i.e., electrical intensity-related refractive index) or the thermo-optical effect (i.e., temperature-related refractive index) and other materials with changeable index of refraction. The material having the electro-optical effect includes, but is not limited to: inorganic electro-optical material (e.g., LiNbO₃), organic/polymer electro-optical material, liquid crystal and the like; the material having the thermo-optical effect includes, but is not limited to, inorganic thermo-optical material (e.g., SiO₂), organic thermo-optical polymer and the like, Comparing with inorganic crystal material, the organic/polymer electro-optical material has the advantages of low cost, being easy to process, higher response speed and higher non-linear coefficient (Advances in Polymer Science, 2002 □vol 158, Springer-Verlag Berlin Heidelberg).

### BRIEF DESCRIPTION OF THE DRAWINGS

In the following, embodiments of the invention will be described in detail in conjunction with the accompanying drawings, in which:

FIG. 1 illustrates a basic structure of the WCSPR.

FIG. 2 is a typical schematic diagram illustrating the reflectivity of the WCSPR versus the incident angle.

FIG. 3 is a graph illustrating the calculated resonance angle and strength of the WCSPR peak versus the refractive index of the detected layer.

FIG. 4 is a graph illustrating the calculated resonance angle and strength of the WCSPR peak versus the thickness of the detected layer.

FIG. 5 is a schematic diagram illustrating an electro-optically modulated WCSPR sensing system device comprising a prism and a tri-layer structure of metal layer/dielectric waveguide layer/metal layer.

FIG. 6 is a graph illustrating the strength of the reflected light signal of the WCSPR effect versus the refractive index of the detected layer, under the condition that the refractive index of the dielectric waveguide layer is changed.

FIG. 7 is a graph illustrating the strength of the reflected light signal of the WCSPR effect versus the thickness of the detected layer, under the condition that the refractive index of the dielectric waveguide layer is changed.

FIG. 8 illustrates a measuring system using a sensor chip array according to the embodiments of the invention.

FIG. 9 is a schematic diagram illustrating the change of different refractive indices of the detected layer under voltage modulation.

FIG. 10 is a schematic diagram illustrating the change of different to thicknesses of the detected layer under voltage modulation.

### EMBODIMENTS OF THE INVENTION

According to the invention, information on a detected sample is obtained by changing parameters of optical properties of the dielectric waveguide layer, using the WCSPR structure as the basic structure of sensing measurement. Thus, it is possible to implement SPR sensors with high resolution, SNR, and to improve response time and to realize large-scale multi-channel scanning.

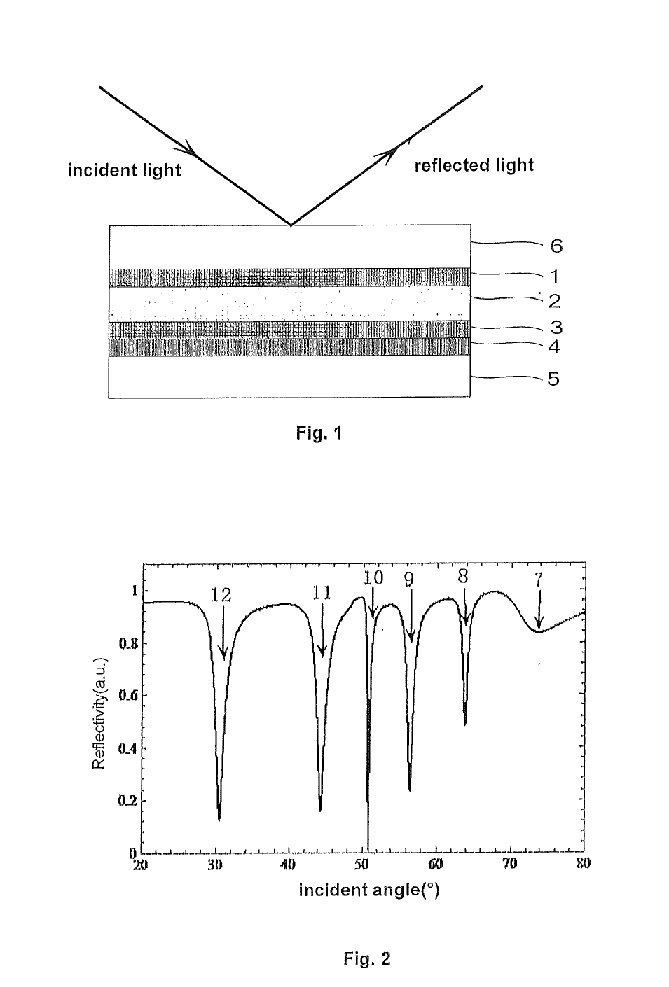

The WCSPR structure illustrated in FIG. 1 comprises a multilayer film structure. The SPR excited at the interface between the metal layer 3 and the detected layer 4 is affected by the waveguide modal property of the dielectric waveguide layer 2. Since the SPR can only be excited by a TM mode of the incident light, the reflection of the TM mode at the interface between the dielectric waveguide layer 2 and the metal layer 3 may be expressed as:

$${r}_{i , k} = \frac{{k}_{zl} {ɛ}_{k} - {k}_{zk} {ɛ}_{l}}{{k}_{zl} {ɛ}_{k} + {k}_{zk} {ɛ}_{l}} \qquad ( 3 )$$

where r_{i,k} is the reflectivity of the light wave at the interface between the ith and kth layers, i,k=0, 1, 2 . . . , k_{zi}=k₀\sqrt{∈ᵢ−kₓ²} is the z-component of the wave vector in the ith layer, k_{zk} is the z-component of the wave vector in the kth layer, ∈ₖ is the dielectric constant of the kth layer material, and ∈ᵢ is the dielectric constant of the ith layer material. The theoretical reflectivity equation is as follows:

$$\begin{matrix}R = {\vert \frac{{r}_{0 , 1} + {r}_{1 , 2 , … , n} exp ( 2 j {d}_{1} {k}_{1} )}{1 + {r}_{0 , 1} {r}_{1 , 2 , … , n} exp ( 2 j {d}_{1} {k}_{1} )} \vert}^{2} \\ where \text{:} & ( 4 ) \\ {r}_{n - 2 , n - 1 , n} = \frac{{r}_{n - 2 , n - 1} + {r}_{n - 1 , n} exp ( 2 j {d}_{n - 1} {k}_{zn - 1} )}{1 + {r}_{n - 2 , n - 1} {r}_{n - 1 , n} exp ( 2 j {d}_{n - 1} {k}_{zn - 1} )} & ( 5 )\end{matrix}$$

For the resonance mode of the optical waveguide, the phase of the reflected light may be expressed as follows:

2k_{zi}d=2mπ−(Φ_{i-1,i}+Φ_{i,i+1}), m=0,1,2 . . . (6)

where d is the thickness of the waveguide layer, j is the sign of the imaginary part, n is the number of the waveguide layers, 0, 1 . . . are the indices of the waveguide layers, R is the reflectivity of the light that is incident from the waveguide layer 0, reflected at respective waveguide layers one by one and returns to the waveguide layer 0; r_{n-2,n-1,n} is the reflectivity of the light that is incident at the waveguide layer n−2 and returns to the waveguide layer n−2 after being reflected at waveguide layers n−1 and n; k_{z(n-1)} is the z-propagation coefficient of the light wave in the waveguide layer n−1; in k_{zi}, i indicates the index of the waveguide layer and m is the index of the mode in the waveguide, Φ_{i,i+1} is the phase shift caused by the reflection of the light wave at the interface between two adjacent layers.

FIG. 2 is a schematic diagram illustrating the relationship between the reflectivity and the incident angle, calculated according to Equation (4). In FIG. 2, arrow 7 indicates a notch (descending peak) in the reflectivity caused by the SPR on the surface of the metal layer 1; arrows 8, 9, 11 and 12 indicate notches (descending peaks) in the reflectivity caused by the coupled waveguide mode excited at the dielectric layer 2 by the evanescent waves transmitted through the metal layer 1; and arrow 10 indicates a notch (descending peak) in the reflectivity caused by the WCSPR generated at the surface of the metal layer 3. It can be seen from this figure that the notches (descending peaks) corresponding to the first two of the modes generated in the optical waveguide are relatively wide, while the reflection peak of the WCSPR is sharper. Since the reflection peak (notch) caused by the WCSPR is sharper than those caused by the optical waveguide or the conventional SPR, the detection method based on the WCSPR principle has a higher SNR.

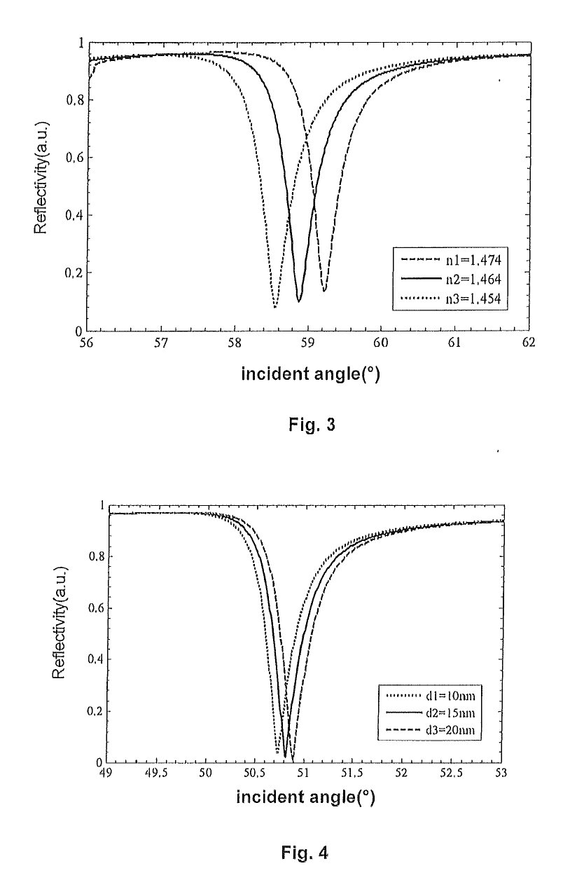

FIGS. 3 and 4 illustrate the effect of the changes in the refractive index (n=1.454-1.474) and the thickness (d=10 nm-20 nm) of the detected layer on the WCSPR signals, respectively. In FIG. 3, the wavelength of the incident laser is 980 nm, the prism is a ZF-7 prism, the material of both metal layers is gold (Au), which has a dielectric constant of −40.3+2.8i and a thickness of 20 nm; the intermediate dielectric waveguide layer has a refractive index of 1.638 and a thickness of 1.7 μm. When the refractive index changes from 1.454 to 1.474, the position of the peak is shifted by 0.68°. It can be seen from FIGS. 3 and 4 that the angle of the WCSPR is shifted significantly, showing that the WCSPR mode is very sensitive to the change of the properties of the detected layer. It has been revealed by study that the WCSPR has a better sensitivity to the change of the parameters of the physical properties of the analyzed layer than other SPR effects.

Now, a WCSPR structure with a dielectric waveguide layer having the electro-optical effect will be described as an example. Electro-Optical Effect (also referred to as Pockels Effect) is a non-linear optical effect. The optical refractive index of an optical material having the electro-optical effect may be changed by applying an electrical field. In this sense, the electro-optical effect is an electrical field-related refractive index effect. The distribution of the refractive indices in the electro-optical material may be described using the index ellipsoid model. When a voltage is applied to the z-axis of the system, a new index ellipsoid equation is written as:

$$( \frac{1}{{n}_{0}^{2}} + {γ}_{13} E ) {n}_{x}^{2} + ( \frac{1}{{n}_{0}^{2}} + {γ}_{13} E ) {n}_{y}^{2} + ( \frac{1}{{n}_{e}^{2}} + {γ}_{33} E ) {n}_{z}^{2} = 1 \qquad ( 7 )$$

Where nₒ and nₑ are the Ordinary Refractive Index and Extraordinary Refractive Index of the electro-optical material respectively, E is the applied electrical field, γ₁₃ and γ₃₃ are the components of the electro-optical coefficient tensor of the material. The change in the refractive index caused by the electrical field of Equation (7) is as follows:

$$Δ {n}_{x} = Δ {n}_{y} = - \frac{1}{2} {n}_{0}^{3} {γ}_{13} {E}_{t} \\ and \\ Δ {n}_{z} = - \frac{1}{2} {n}_{e}^{3} {γ}_{33} E \qquad ( 8 )$$

It can be seen from the above equation that the change in the refractive index Δn is proportional to the change in the strength of the electrical field E.

According to Equation (8), the change in the refractive index of the electro-optical material is linearly related to the external electrical field and the electro-optical coefficient of the material. Thus, the change of the physical properties on the surface of the sensor caused by molecular adsorption and the like may be indicated with the change of the refractive index, which may be detected using the electro-optical effect of the optical waveguide.

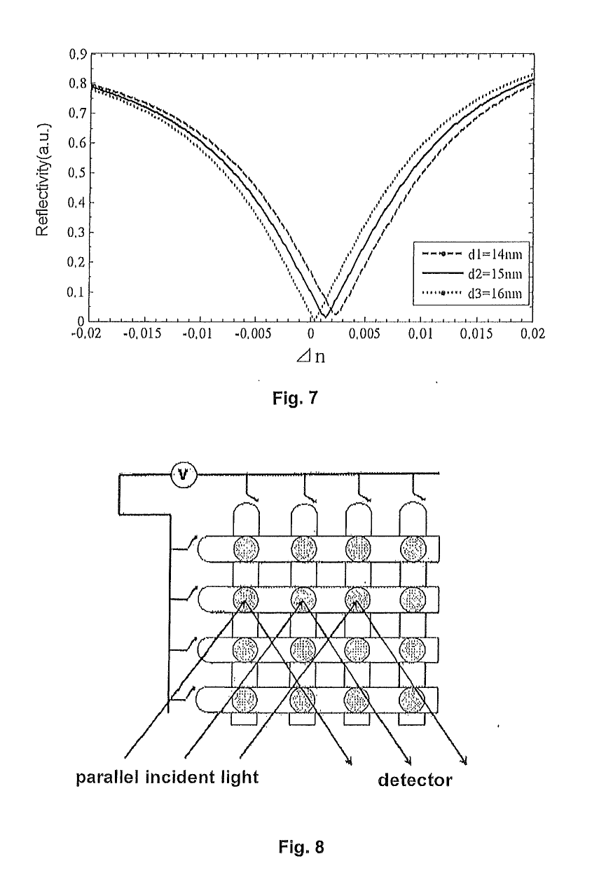

According to the invention, when the wavelength and angle of the incident wave are fixed, the condition of the optical WCSPR is changed by tuning the optical properties of the material of the dielectric waveguide layer 2 in the WCSPR sensing structure, thereby scanning the SPR signals and obtaining information. During the scan, each time the properties of the dielectric waveguide layer are changed, e.g., the modulating voltage is changed, the properties of the reflected light, such as the intensity, of the WCSPR effect are is detected. FIGS. 6 and 7 illustrate the strength of the reflected light in the WCSPR obtained using the interrogation scheme. For the WCSPR signal, a WCSPR signal peak may be found for a certain refractive index of the waveguide layer, by changing the refractive index of the dielectric layer. Meanwhile, when the physical properties of the detected layer 4 are changed and the other conditions remain the same, the curves obtained by the interrogation scheme of changing the refractive index will change accordingly. Therefore, the amount of changes in the physical properties, e.g., dielectric coefficient, thickness, etc. of the detected layer may be determined according to the properties of the obtained WCSPR signal, e.g., the amount of change in the refractive index corresponding to the position of the peak, intensity of the signal and the like. When applied as sensor chips, the changes of the physical properties of the detected layer generally correspond to a certain biochemical or physiochemical property of the measured sample. Thus, the material of the detected layer may be chosen as one corresponding to a biochemical or physiochemical property of the measured sample. The substance related to the biochemical or physiochemical property of the sample thereof interacts with the selectivity of the detected layer 4, thereby changing the physical properties of the detected layer 4. A certain biochemical or physiochemical property of the sample to be detected is thus selectively obtained according to the change of the properties of the WCSPR signal.

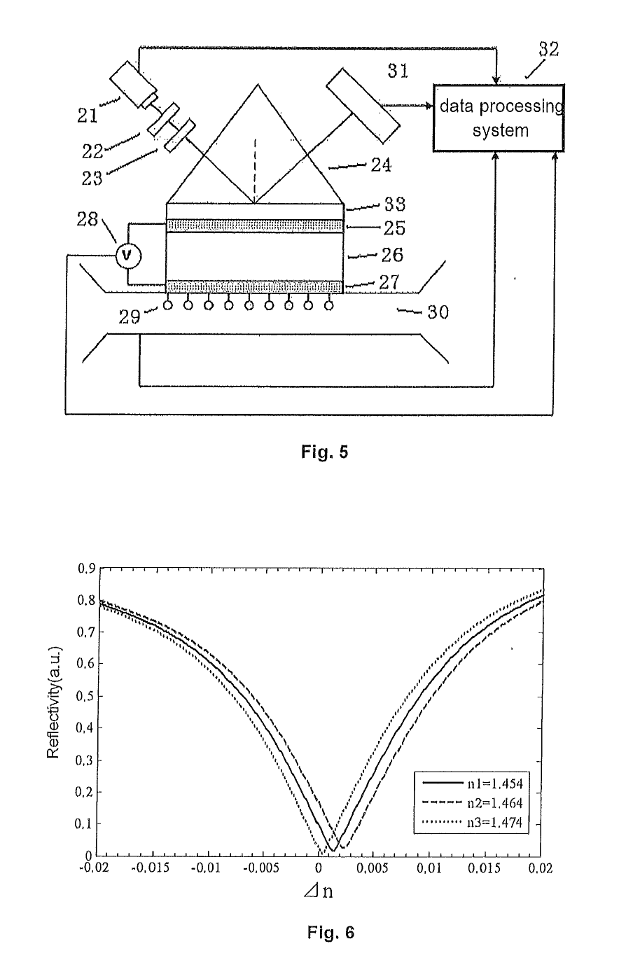

FIG. 5 illustrates a measuring system employing an electro-optically modulated WCSPR sensor. In the system, the electro-optically modulated WCSPR sensor chip includes a ZF-7 glass substrate 33, a second metal layer 25 and a first metal layer 27 disposed on the glass substrate, and a dielectric waveguide layer 26 disposed between the first and second metal layers. Both the first and second metal layers are gold films with a thickness of 20 nm. The material of the dielectric waveguide layer 26 is chromophore molecule EO-FTC (2-(3-cyano-4(E)-2-(5-(4-(lignocaine) cinnamenyl)-3,4-PEDT-2-) ethylene)-5,5-DMFU-2(5H)-Gs) malononitrile) with high non-linear coefficient and a thickness of 1.7 μm. An intermediate layer (not shown in FIG. 5) of 2 nm-thick Cr is plated between the second metal layer 25 and the glass substrate 33, thereby enhancing the adhesive force of the metal on the glass substrate. The material of the intermediate layer may also be Cr, Ti, Ni or the alloy thereof, and the thickness of which is selected as not to harm the detection function of the WCSPR sensor and the tuning function of the dielectric waveguide layer, which is normally controlled between 0.2 nm to 10 nm.

The material of the first and second metal layers may be selected from other kinds of metal, alloy or metallic compound. The other kinds of metal may be silver (Ag), chromium (Cr), Copper (Au), Aluminum (Al) and the like. The alloy may be Cr—Au, Ti□Au, Au□Ag, Cu□Ni, Al□Ni and the like. The metallic compound may be a transparent conductive material such as ITO. The irregularity of the thickness of the first and second metal layers should be restricted in a range of not obviously harming the detection sensitivity and accuracy of the sensor. Preferably, the thickness of the first and second metal layers is 10 nm to 200 nm, and more preferably, 20 nm to 50 nm, and both of which may be in a single layer or multilayer structure.

Meanwhile, isolating layers may be inserted between each of the layers to prevent substance leakage. The isolating layers may be made of a material of Al₂O₃ or SiO₂, and the parameters such as properties and thickness of the material of the isolating layers should not harm the detection function of the WCSPR sensor and the tuning function of the dielectric waveguide layer. Normally the thickness should be controlled in a range of 10 to 500 nm, and preferably 100 to 200 nm.

A detected layer is further disposed on top of the second metal layer. The detected layer may be a label layer adsorbed to the surface of the underlying metal layer by physical adsorption of the metal surface or through a chemical reaction in which a covalent bond is formed between the metal surface and the chemical material. The molecules of the label correspond to the detected substance. Specific adsorption is formed through the interaction between molecules (e.g., the van der Waals force, hydrogen bond, coordination bond and the like), thus, parameters of the label layer, such as the thickness or refractive index, are changed, which will be reflected in the SPR signal. That is how the detection is done. If the refractive index of the detected substance itself may change, the detected layer itself can also be the detected substance, such as a detected liquid. In this case, a conveying system needs to be attached, so as to control the relevant parameters such as feeding and exiting of the substance in this layer. In this embodiment, 16-mercaptohexadecanoic carboxylic acid is used as the material of the detected layer, which has a refractive index of 1.464. Other detected substance, decorative substance or label substance and the combinations thereof may be used based on the requirement of the sample to be detected.

The first and second metal layers in the sensor chip principally have the following functions: (i) to generate the SPR effect; (ii) under the electro-optical modulation mode, to function as electrodes to provide voltage across both ends of the dielectric waveguide layer, so as to tune the properties of the dielectric waveguide layer, such as the refractive index; (iii) to protect the dielectric waveguide layer and prevent permeation and erosion from foreign substance; and (iv) to provide a detecting interface for the detected layer.

The method for manufacturing the sensor comprises the steps of:

(1) First, plating the ZF7 glass substrate with a chromium layer of 2 nm, then forming a gold film of 20 nm by evaporation as a first metal layer;

(2) Next, mixing EO-FTC with a tetrachloroethane solution of polycarbonate (PC) according to a proportion of 10 to 15% in weight and then spin coating the mixture on the first metal layer to form a thin film of 1.7 μm;

(3) Next, using evaporation to form a gold film of 20 nm as the second metal layer;

(4) Finally, using monolayer adsorption method (forming an S—Au bond) to make a monolayer of 16-mercaptohexadecanoic carboxylic acid on the second metal layer as the detected layer.

In the above manufacturing process, the method for preparing the first and second metal layers may be, but not limited to, such methods for preparing a metal film as vacuum evaporation, vacuum sputtering, chemical vapor deposition or electrochemical deposition. The method for preparing the dielectric waveguide layer may be, but not limited to, such methods for preparing a film as vacuum evaporation, spin coating, chemical vapor deposition and the like. The method for preparing the detected layer may be, but not limited to, such methods for preparing a film as Molecular Self-Assembly, stamp print and the like.

Other than the sensor, the measuring system of FIG. 5 further includes an infrared laser source with a wavelength of 980 nm, a polarizing plate and a half-wave plate arranged on the output light path of the laser source, a 45° rectangular prism, a detector for detecting the intensity of the reflected light, a voltage modulator, a sample pool, a conveying system and a data processing system. Refractive index matching liquid is used to bond the slant surface of the prism with the glass substrate of the sensor. The detector may be a single plate detector, a linear array detector or a CCD planer array detector and the like.

In the above devices, the light source, preferably a laser source, is capable of emitting stable narrow-band monochromatic light, the wavelength of which is preferably not easily absorbed by the material of the dielectric waveguide layer. The refractive index of the prism should match that of the substrate of the sensor. The prism may be a semi-cylindrical or 45°/60° rectangular prism. The 45° rectangular prism of the embodiment is also made of ZF-7 glass and the refractive index of which is 1.7761 for wavelengths of 980 nm.

The data processing system in the embodiment has the following functions:

a) controlling the output wavelength of the light source 1;

b) controlling the specific voltage applied to the dielectric waveguide layer by the voltage modulator 8;

c) controlling the related parameters of the biochemical conveying system;

d) collecting and processing data of the light signal obtained by the detector;

e) giving the information on the refractive index or thickness of the detected layer, according to the voltage of the voltage modulator and the light signal to information captured by the detector;

The method of using the above measuring system is as follows:

(1) allowing the polarized light emitted from the polarized light generator to be incident on the sensor chip, adjusting the incident angle of the incident polarized light to allow parameters of emergent light on the detector to be at a characteristic position of the resonance peak, then fixing the incident angle;

(2) feeding the detected sample into the conveying system;

(3) adjusting the voltage modulator 8 to apply an electrical field on the sensor chip, making the parameters of the emergent light on the detector return to the characteristic position of the resonance peak; and

(4) obtaining a biochemical or physiochemical property of the detected sample by comparing the applied voltage of step (3) to a correspondence relation between known voltage and biochemical or physiochemical properties of the detected sample.

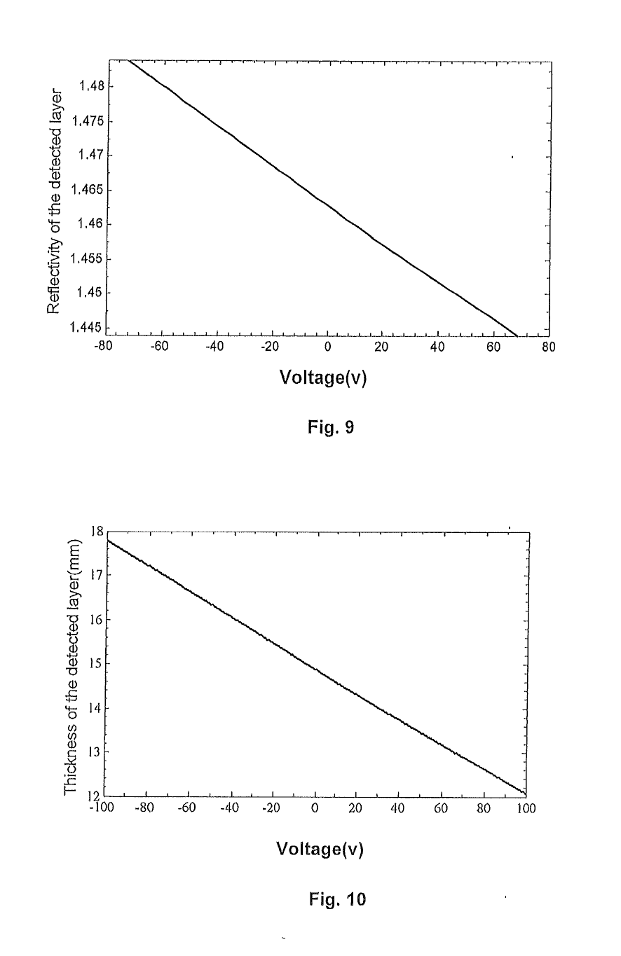

In this embodiment, the incident angle is fixed at 50.87°, the electro-optic coefficient of the dielectric waveguide layer EO-FTC is 30 pm/V. The WCSPR peak in the strength of the emergent light is chosen as a characteristic signal. It is found that the modulated curves of the refractive index and thickness of the measured layer have a high linearity versus the voltage, and the slope of which are 0.00028 RIU/V (FIG. 9) and 0.029 nm/V (FIG. 10), respectively. Thus, the sensitivity of measurement of the refractive index is 3571 V/RIU, and the sensitivity of measurement of the thickness is 34 V/nm. When the voltage resolution corresponding to the WCSPR characteristic signal is up to 1 mV, the measurement resolution of the refractive index is up to 2.8×10⁻⁷ RIU, and the measurement precision resolution of the thickness is up to 2.9×10⁻⁵ nm. That is to say, as long as there are slight changes in the refractive index and/or thickness of the detected layer caused by the sample to be measured, the measuring system of the embodiment can detect them.

The measuring system according to the embodiment may also utilize voltage interrogation, in which the angle of the incident light is chosen to be close to the angle that may cause the WCSPR peak and is fixed during the interrogation process. Upon obtaining the change pattern of the WCSPR signal by changing the optical properties of the dielectric waveguide layer, parameters such as the position, width, and amplitude of the nadir of the WCSPR peak may also be calculated using curve-fitting. Information such as the refractive index or thickness of the detected layer are then obtained using the matching equation comprising Fresnel Equation or the known calibration coefficient, both of which are well-known to those skilled in the art.

FIG. 8 illustrates the structure of a multi-channel sensor chip array for which parallel interrogation via voltage may be realized. Here, metal layers on both sides of the dielectric waveguide layer are made up of a plurality layers of metal strips parallel but not electrically connected to each other; the width of which is wider than the propagation length of the SP waves generated by resonance. Thus, each layer forms independent metal strip electrodes. The strip structures of the first metal layer and the second metal layer are arranged perpendicular to each other. The dielectric waveguide layer between the first and second metal layers is made up of electro-optical material. The intersecting sections 4 of the strip electrodes of the first metal layer and that of the second metal layer form small WCSPR sections, that is, small working points of pixels are formed. The modulating voltage applied to this section may be controlled separately by setting the voltage drop between electrodes in the upper/lower layer. The reflected light signals on respective working points are received and detected by a light detector array, such as a CCD array.

The method for manufacturing the above sensor chip array is as follows:

1. First, preparing a plurality of metal strips parallel to but electrically insulated from each other on the substrate to form the second metal layer;

2. Next, preparing the dielectric waveguide layer and the plurality of metal strips parallel to but electrically insulated from each other that function as the first metal layer sequentially in a bottom-up order, and the metal strips in the first metal layer being perpendicular to the metal strips in the second metal layer.

The system employing the sensor chip array is similar to the system using a single sensor shown in FIG. 5, with the following exceptions: the beam emitted by the polarized light generator is a wide beam or a beam array; the detector has to be a detector array, such as a CCD array. The principle of voltage interrogation is to the same for this system. When a voltage is applied to the electrodes, the strength or angle of the SPR signal will be changed, which will be reflected in the corresponding detecting pixel of the detector array. The SPR signals and their variations of all working points may be obtained simultaneously by the detector array. The design of such a measuring system allows for the realization of is biochemical dynamic procedures that may detect numerous working points concurrently in a quick and efficient way, thereby realizing multi-channel real-time biochemical detection.

The dielectric waveguide layer in the sensor and sensor chip array may be prepared using an electro-optical material. The available electro-optical materials include inorganic crystal material, organic/polymer electro-optical material, such as LiNbO₃, KDP, ADP, KD*P, LiTaO₃ or DAST. The materials should have relatively large electro-optic coefficient, a homogenous optical property and a good film forming property. The metal layers as the electrodes should have pins for connecting to voltage interrogation control signal.

The above embodiments are described with reference to the electro-optical material. According to the invention, those skilled in the art will understand that materials other than the electro-optical material, such as magneto-optical material, thermo-optical material or acousto-optical material, may also be used, and a different field-control device should be used accordingly.

The refractive index of the magneto-optical material is responsive to the change of the magnetic field, that is, it is a material having the magneto-optical effect. Such materials include metal magneto-optical material, such as Mn—Bi based alloy, ferrite magneto-optical material, such as garnet Bi—Gd—Fe—Ga—O based ferrite; amorphous magneto-optical material, such as Gd—Co based amorphous magneto-optical alloy.

The thermo-optical material is a material whose refractive index is responsive to the change of temperature, that is, it is a material having the thermo-optical effect, such as the optical glass and the like.

The acousto-optical material has a refractive index responsive to the change of properties of acoustic waves, that is, it is a material having the acousto-optical effect, such as PbMoO₄, TeO₂, Tl₃AsS₄ and the like.

In the above sensor chip, the thickness of the dielectric waveguide layer has to be strictly controlled and selected, such that the waveguide mode needed for the measuring is obtained. The thickness of the dielectric waveguide layer should be larger than or equal to the wavelength of the incident wave and less than 100 μm, and preferably between 1 μm and 10 μm.

The material of the substrate is optical glass or polymer, and the parameters such as the thickness and optical loss of the substrate material should not harm the detection function of the sensor.

The embodiments described in the above are directed at changing the refractive index of the dielectric waveguide layer in various ways. It will be appreciated by those skilled in that art that other parameters of the physical properties of the dielectric waveguide layer, such as its thickness, dielectric constant etc., may also be changed to shift the resonance peak of the reflected light in the sensor chip.

The above descriptions and embodiments elaborate the concept of the invention and the claimed scope thoroughly, those skilled in that art may understand the content of the invention and the claimed scope according to the above disclosure meanwhile, they may understand that the above embodiments does not intend to limit the claims of the invention.

1. A sensor chip based on Waveguide Coupled SPR (WCSPR) effect comprising a substrate, a dielectric waveguide layer disposed on the substrate and a first metal layer disposed on the dielectric waveguide layer, wherein parameters of physical properties of the dielectric waveguide layer are tunable.

2. The sensor chip as recited in claim 1, characterized in that it further comprises a second metal layer disposed between the substrate and the dielectric waveguide layer.

3. The sensor chip as recited in claim 1, characterized in that the parameters of the physical properties are index of refraction or thickness.

4. The sensor chip as recited in claim 1, characterized in that it further comprises a detected layer disposed on the other side of the second metal layer.

5. The sensor chip as recited in claim 4, characterized in that a material of the detected layer comprises a substance to be detected, a decorative substance or a label substance.

6. The sensor chip as recited in claim 1, characterized in that a material of the dielectric waveguide layer is an electro-optical material, a magneto-optical material, a thermo-optical material or an acousto-optical material.

7. The sensor chip as recited in claim 6, characterized in that the electro-optical material comprises an inorganic electro-optical material, organic electro-optical material, polymer electro-optical material and compound electro-optical material.

8. The sensor chip as recited in claim 7, characterized in that the inorganic electro-optical material is LiNbO₃, KDP, ADP, KD*P or LiTaO₃, and the organic electro-optical material is DAST.

9. The sensor chip as recited in claim 6, characterized in that the magneto-optical material comprises metal magneto-optical material, ferrite magneto-optical material and amorphous magneto-optical material.

10. The sensor chip as recited in claim 9, characterized in that the magneto-optical material is Mn—Bi based alloy, the ferrite magneto-optical material is garnet Bi—Gd—Fe—Ga-0 based ferrite, and the amorphous magneto-optical material is Gd—Co based amorphous alloy.

11. The sensor chip as recited in claim 6, characterized in that the thermo-optical material is optical glass.

12. The sensor chip as recited in claim 6, characterized in that the acousto-optical material comprises PbMoO₄, TeO₂ and Tl₃AsS₄.

13. The sensor chip as recited in claim 1, characterized in that a material of the substrate is optical glass or polymer.

14. The sensor chip as recited in claim 1, characterized in that a thickness to of the dielectric waveguide layer is less than 100 μm.

15. The sensor chip as recited in claim 1, characterized in that a thickness of the dielectric waveguide layer is 1 μm to 10 μm.

16. The sensor chip as recited in claim 1, characterized in that a thickness of the first metal layer is 10 nm to 200 nm, preferably in a range of 20 nm to 50 nm.

17. The sensor chip as recited in claim 2, characterized in that a thickness of the second metal layer is 10 nm to 200 nm, preferably in a range of 20 nm to 50 nm.

18. The sensor chip as recited in claim 1, characterized in that the material of the first and second metal layers is one kind of metal, an alloy or a metallic compound.

19. The sensor chip as recited in claim 18, characterized in that the metal is Au, Ag, Cr, Cu or Al, the alloy is Cr—Au, Ti—Au, Au—Ag, Cu—Ni or Al—Ni, and the metallic compound is ITO.

20. The sensor chip as recited in claim 1, characterized in that the first metal layer is a single layer or multilayer structure.

21. The sensor chip as recited in claim 2, characterized in that the second metal layer is a single layer or multilayer structure.

22. The sensor chip as recited in claim 1, characterized in that the dielectric waveguide layer is a single layer or multilayer structure.

23. The sensor chip as recited in claim 1, characterized in that it further comprises an intermediate layer for strengthening adhesive forces between the layers.

24. The sensor chip as recited in claim 23, characterized in that a material of the intermediate layer is Cr, Ni or Ti.

25. The sensor chip as recited in claims 23 to 24, characterized in that a thickness of the intermediate layer is 0.1 to 10 nm.

26. The sensor chip as recited in claim 1, characterized in that it further comprises an isolating layer for preventing substance leakage between the layers.

27. The sensor chip as recited in claim 26, characterized in that a material of the isolating layer is Al₂O₃ or SiO₂.

28. The sensor chip as recited in claim 26, characterized in that a thickness of the isolating layer is 10 to 500 nm.

29. The sensor chip as recited in claim 26, characterized in that a thickness of the isolating layer is 100 to 200 nm.

30. A manufacturing method of the sensor chip of any of claims 1 to 29, comprising preparing each layer structure on the substrate sequentially in a bottom-up order.

31. The manufacturing method as recited in claim 30, characterized in that a method for preparing the first and second metal layers is Vacuum Evaporation, Electrochemical Deposition, Chemical Vapor Deposition, or Vacuum Sputtering.

32. The manufacturing method as recited in claim 30, characterized in that a method for preparing the dielectric waveguide layer is evaporation, Chemical Vapor Deposition, or spin-coating.

33. A measuring system employing the sensor chip of claims 1 to 29 comprising a polarized light generator, a light coupler, a light detector, a conveying system, a control system and a field control device for applying an electrical field, magnetic field, acoustic field or temperature control to the dielectric waveguide layer, wherein the polarized light emitted from the polarized light generator is incident onto the substrate of the sensor chip through the light coupler and then fed into the light detector after being reflected by the sensor chip.

34. The measuring system as recited in claim 33, characterized in that the polarized light generator comprises a light source, a polarizing plate and a half-wave plate sequentially arranged in a light path.

35. The measuring system as recited in claim 33, characterized in that the light coupler is a prism or a grating.

36. The measuring system as recited in claim 33, characterized in that the light detector is a semiconductor light intensity detector or a CCD.

37. A measuring method used in the measuring system of claims 33 to 36, comprising the steps of:
(1) projecting the polarized light emitted from the polarized light generator to the sensor chip and adjusting an incident angle of the incident polarized light to allow parameters of the emergent light on the detector to be at a characteristic position of the resonance peak;
(2) feeding a detected sample into the conveying system;
(3) adjusting the field control device to apply an external field on the sensor chip, making parameters of the emergent light on the detector return to the characteristic position of the resonance peak; and
(4) obtaining a biochemical or physiochemical property of the detected sample by comparing the applied external field of step (3) to a correspondence relation between known external fields and biochemical or physiochemical properties of the detected sample.

38. The measuring method as recited in claim 37, characterized in that the resonance peak is a WCSPR peak.

39. The measuring method as recited in claim 37, characterized in that the parameter of the emergent light is light intensity or phase, and the characteristic position is where the intensity of the emergent light reaches the minimum or has a point of inflection.

40. An array of sensor chips of any of claims 1 to 29 comprising a second metal layer, a dielectric waveguide layer and a first metal layer sequentially disposed on a substrate, wherein the first and second metal layers are each made up of a plurality of thin metal film strips parallel to and electrically insulated from each other; a width of the thin metal film strip is larger than a propagation length that may excite SP waves; the thin metal film strips of the first metal layer and those of the second metal layer overlap with each other, and the dielectric waveguide layer is arranged between the above and below thin metal film strips at the intersecting sections.

41. The array of sensor chips as recited in claim 40, characterized in that the thin metal film strips of the first metal layer are vertical to the thin metal film strips of the second metal layer.

42. A measuring system employing the sensor chip array of claims 40 and 41 comprising a polarized light generator, a light coupler, a light detector, a conveying system, a control system and a field control device for applying an electrical field, magnetic field, acoustic field or temperature control to the dielectric waveguide layer, the polarized light emitted from the polarized light generator is incident onto the substrate of the sensor chip through the light coupler and then fed into the light detector after being reflected by the sensor chip.

43. The measuring system as recited in claim 42, characterized in that an output of the polarized light generator is preferably a wide beam polarized light or a polarized light array.

44. The measuring system as recited in claim 42, characterized in that the optical coupler is preferably a grating, a prism or a prism array.

45. The measuring system as recited in claim 42, characterized in that the light detector is a semiconductor light intensity detector array or a CCD.
